(19) United States
(12) Patent Application Publication
(10) Pub. No.: US 2017/0257979 A1
(43) Pub. Date: Sep. 7, 2017

(54) WATER COOLING DEVICE

(71) Applicant: AURAS Technology Co., Ltd., New Taipei City (TW)

(72) Inventors: An-Chih Wu, New Taipei City (TW); Mu-Shu Fan, New Taipei City (TW); Chien-Yu Chen, New Taipei City (TN); Chien-Chih Su, New Taipei City (TW)

(21) Appl. No.: 15/435,452

(22) Filed: Feb. 17, 2017

Related U.S. Application Data
(60) Provisional application No. 62/301,801, filed on Mar. 1, 2016.

(51) Int. Cl. H05K 7/20

(52) U.S. Cl. CPC H05K 7/20263; H05K 7/20272; H05K 7/20281

(57) ABSTRACT

A water cooling device includes a communication structure, a water cooling structure and a driving device. The communication structure includes a first chamber and a second chamber. The water cooling structure includes plural water tubes. The driving device is installed in at least one of the first chamber and the second chamber. The first chamber includes a water inlet and plural inlet ports. The second chamber comprises a water outlet and plural outlet ports. The water inlet and the water outlet are formed in the same lateral surface of the communication structure. At least two additional lateral surfaces of the communication structure are located beside the water cooling structure. The plural water tubes are in communication with the plural inlet ports and the plural outlet ports. A cooling medium is guided to flow through the plural water tubes.

### CROSS-REFERENCE TO RELATED APPLICATION

This application claims priority to U.S. Provisional Patent Application No. 62/301,801 entitled “WATER COOLING DEVICE” filed Mar. 1, 2016, the contents of which are incorporated herein by reference.

### FIELD OF THE INVENTION

The present invention relates to a water cooling device, and more particularly to a water cooling device for effectively increasing the space utilization and the heat dissipating performance.

### BACKGROUND OF THE INVENTION

As the performance of electronic products gradually increases, the integrated circuit structures in the electronic products become more and more complicated. Consequently, during operation of the electronic product, a great amount of heat is generated. If the heat cannot be dissipated away quickly, the inner integrated circuit of the package chip is possibly burnt out. For maintaining the normal operations of the integrated chip, it is necessary to increase the heat dissipating efficiency.

For example, a water cooling device is one of the heat dissipation structures that are applied to the electronic products. The water cooling device uses liquid to remove heat from the chip. After the heat exchange between the liquid and the ambient air is performed, the absorbed heat is radiated to the air.

However, in the conventional water cooling system, the water cooling device is connected to an external pipe system through at least one pump. The pump is used as a motive power source for driving the liquid. Since the pump in operation also generates heat, the amount of heat to be removed in the corresponding site is increased indirectly.

Moreover, if the heat generated by the operating pump is not effectively dissipated away, the efficiency of the pump is impaired. Under this circumstance, the overall heat dissipating efficacy of the water cooling device is not satisfied.

Moreover, in the conventional water cooling system, the installation location of the pump is restricted. For example, in case that the water cooling system is designed to dissipate heat of an object, the pump is usually installed in the available space within the object. In other words, the space utilization and design of the conventional water cooling system is limited.

Therefore, there is a need of providing a water cooling device for effectively increasing the heat dissipating performance and the overall space utilization in order to overcome the above drawbacks.

### SUMMARY OF THE INVENTION

For solving the drawbacks of the conventional technologies, the present invention provides a water cooling device for preventing the generated heat of a driving device from diffusing to the heat dissipation region of the water cooling system while effectively increasing the space utilization of the overall water cooling system.

In accordance with an aspect of the present invention, there is provided a water cooling device. The water cooling device includes a water cooling structure, a communication structure and a driving device. The water cooling structure includes plural water tubes. The communication structure includes a first chamber and a second chamber. The first chamber comprises a water inlet and plural inlet ports. The second chamber includes a water outlet and plural outlet ports. The driving device is installed in at least one of the first chamber and the second chamber. The water inlet and the water outlet are formed in the same lateral surface of the communication structure. At least two additional lateral surfaces of the communication structure are located beside the water cooling structure. The plural water tubes are in communication with the plural inlet ports and the plural outlet ports. A cooling medium is guided to flow through the plural water tubes.

In an embodiment, the plural inlet ports are formed in a surface of the first chamber that is in communication with the plural water tubes, and the plural outlet ports are formed in a surface of the second chamber that is in communication with the plural water tubes.

In an embodiment, the water cooling structure at least includes a first water-cooling radiator and a second water-cooling radiator. The first water-cooling radiator includes first water tubes of the plural water tubes. The second water-cooling radiator includes second water tubes of the plural water tubes. The communication structure is arranged between the first water-cooling radiator and the second water-cooling radiator.

In an embodiment, a first surface of the first water-cooling radiator is located beside a first one of the at least two additional lateral surfaces. A first water tank is in communication with the first water tubes and installed on a second surface of the first water-cooling radiator. A first surface of the second water-cooling radiator is located beside a second one of the at least two additional lateral surfaces. A second water tank is in communication with the second water tubes and installed on a second surface of the second water-cooling radiator.

In an embodiment, a portion of the cooling medium flows along a first flow-guiding direction and flows through the first chamber, the plural inlet ports, a first portion of the first water tubes, the first water tank, a second portion of the first water tubes, the plural outlet ports, the second chamber and the water outlet sequentially. Consequently, a first flow-guiding path is defined.

In an embodiment, a portion of the cooling medium flows along a second flow-guiding direction and flows through the first chamber, the plural inlet ports, a first portion of the second water tubes, the second water tank, a second portion of the second water tubes, the plural outlet ports, the second chamber and the water outlet sequentially. Consequently, a second flow-guiding path is defined.

In an embodiment, the water cooling structure includes a water-cooling radiator with the plural water tubes, and the water-cooling radiator is located beside at least three lateral surfaces of the communication structure.

In an embodiment, a receiving surface of the water-cooling radiator is located beside the at least three lateral surfaces of the communication structure. A first water tank is in communication with the plural water tubes and installed on a first surface of the water-cooling radiator. A second water tank is in communication with the plural water tubes and installed on a second surface of the water-cooling radiator.

In an embodiment, a portion of the cooling medium flows along a flow-guiding direction and flows through the first chamber, the plural inlet ports, a first portion of the plural water tubes, the first water tank, a second portion of the plural water tubes, the second water tank, a third portion of the plural water tubes, the plural outlet ports, the second chamber and the water outlet sequentially. Consequently, a flow-guiding path is defined.

In an embodiment, the water cooling structure is a combination of plural fins, and the plural fins intersect with each other to define the plural water tubes in different densities.

In an embodiment, the communication structure is divided into the first chamber and the second chamber through at least one partition plate.

In an embodiment, the first chamber and the second chamber are horizontally or vertically located beside each other through the at least one partition plate.

In an embodiment, two ends of the driving device are in communication with the water inlet and the plural inlet ports, or the two ends of driving device are in communication with the plural outlet ports and the water outlet.

In accordance with another aspect of the present invention, there is provided a water cooling device. The water cooling device includes a communication structure, a driving device and a water cooling structure. The communication structure includes a first chamber and a second chamber. The first chamber includes a water inlet and plural inlet ports. The second chamber includes a water outlet and plural outlet ports. The driving device is installed in at least one of the first chamber and the second chamber. The water cooling structure is at least located beside a first lateral surface and a second lateral surface of the communication structure, and includes plural water tubes. The plural water tubes are in communication with the plural inlet ports and the plural outlet ports. A cooling medium is guided to flow through the plural water tubes. The water outlet and the water inlet are in communication with an output/input end of a water block. After the cooling medium flows from the first chamber to the plural water tubes and the cooling medium flows to the second chamber through the plural water tubes, the cooling medium exits to the water block and returns to the first chamber through the water block.

In an embodiment, the water inlet and the water outlet are formed in a third lateral surface of the communication structure, and the water block is located near the third lateral surface of the communication structure.

In an embodiment, the plural inlet ports are formed in a surface of the first chamber that is in communication with the plural water tubes, and the plural outlet ports are formed in a surface of the second chamber that is in communication with the plural water tubes.

In an embodiment, the water cooling structure at least includes a first water-cooling radiator and a second water-cooling radiator. The first water-cooling radiator includes first water tubes of the plural water tubes. The second water-cooling radiator includes second water tubes of the plural water tubes. The communication structure is arranged between the first water-cooling radiator and the second water-cooling radiator.

In an embodiment, a first surface of the first water-cooling radiator is located beside one of the first lateral surface and the second lateral surface. A first water tank is in communication with the first water tubes and installed on a second surface of the first water-cooling radiator.

In an embodiment, a first surface of the first water-cooling radiator is located beside one of the first lateral surface and the second lateral surface. A first water tank is in communication with the first water tubes and installed on a second surface of the first water-cooling radiator. A first surface of the second water-cooling radiator is located beside the other of the first lateral surface and the second lateral surface. A second water tank is in communication with the second water tubes and installed on a second surface of the second water-cooling radiator.

In an embodiment, a portion of the cooling medium flows along a first flow-guiding direction and flows through the water inlet, the first chamber, the plural inlet ports, a first portion of the first water tubes, the first water tank, a second portion of the first water tubes, the plural outlet ports, the second chamber and the water outlet sequentially. Consequently, a first flow-guiding path is defined.

In an embodiment, a portion of the cooling medium flows along a second flow-guiding direction and flows through the water inlet, the first chamber, the plural inlet ports, a first portion of the second water tubes, the second water tank, a second portion of the second water tubes, the plural outlet ports, the second chamber and the water outlet sequentially. Consequently, a second flow-guiding path is defined.

In an embodiment, the water cooling structure includes a water-cooling radiator with the plural water tubes. A receiving surface of the water-cooling radiator is at least located beside the first lateral surface, the second lateral surface and the third lateral surface of the communication structure. A first water tank is in communication with the plural water tubes and installed on a first surface of the water-cooling radiator. A second water tank is in communication with the plural water tubes and installed on a second surface of the water-cooling radiator.

In an embodiment, a portion of the cooling medium flows along a flow-guiding direction and flows through the water inlet, the first chamber, the plural inlet ports, a first portion of the plural water tubes, the first water tank, a second portion of the plural water tubes, the second water tank, a third portion of the plural water tubes, the plural outlet ports, the second chamber and the water outlet sequentially. Consequently, a flow-guiding path is defined.

In an embodiment, the water cooling structure is a combination of plural fins, and the plural fins intersect with each other to define the plural water tubes in different densities.

In an embodiment, the communication structure is divided into the first chamber and the second chamber through at least one partition plate.

In an embodiment, the first chamber and the second chamber are horizontally or vertically located beside each other through the at least one partition plate.

In an embodiment, two ends of driving device are in communication with the water inlet and the plural inlet ports, or the two ends of driving device are in communication with the plural outlet ports and the water outlet.

From the above descriptions, the communication structure of the water cooling device is specially designed. In accordance with a feature of the present invention, the water inlet and the water outlet are formed in the same lateral surface of the communication structure. Moreover, the water block is connected with a specified location of the water cooling device that is located at same lateral surface of the communication structure and close to a middle region of the water cooling device. Consequently, the cooling medium flows through the water cooling device to dissipate heat. By this design, the space utilization of the overall water cooling system is increased, and the heat dissipating performance of the water cooling system is enhanced. Moreover, in accordance with the present invention, the driving device of the water cooling device is installed in at least one of the first chamber and the second chamber. Consequently, the generated heat of the driving device is not diffused to the heat dissipation region, and the space utilization of the overall water cooling system is increased. Moreover, at least a water tank and/or at least one water-cooling radiator (or fins) are on the left/right side of the water inlet and the water outlet. Consequently, the variation capability of the flow-guiding direction of the cooling medium and the amount of the cooling medium are increased.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1A is a schematic perspective view illustrating a water block and a water cooling device of a water cooling system according to a first embodiment of the present invention;

FIG. 1B is a schematic perspective view illustrating a portion of the water cooling device as shown in FIG. 1A;

FIG. 1C is a schematic perspective view illustrating a portion of the water tubes as shown in FIG. 1A and a portion of the communication structure and the water tank as shown in FIG. 1B;

FIG. 1D schematically illustrates the flowing direction of the cooling medium in the water tube as shown in FIG. 1C;

FIG. 2 is a schematic perspective view illustrating a portion of a water cooling device according to a second embodiment of the present invention, which is a variant example of FIG. 1B;

FIG. 3 is a schematic perspective view illustrating a portion of the water cooling device according to a second embodiment of the present invention, which is another variant example of FIG. 1B;

FIG. 4A is a schematic perspective view illustrating a portion of the water cooling device according to a fourth embodiment of the present invention;

FIG. 4B is a schematic perspective view illustrating a portion of the water tubes as shown in FIG. 1A and a portion of the communication structure and the water tank as shown in FIG. 4A;

FIG. 4C schematically illustrates the flowing direction of the cooling medium in the water tube as shown in FIG. 4B;

FIG. 5A is a schematic perspective view illustrating a portion of the water cooling device according to a fifth embodiment of the present invention;

FIG. 5B is a schematic perspective view illustrating a portion of the water tubes as shown in FIG. 1A and a portion of the communication structure and the water tank as shown in FIG. 5A;

FIG. 5C schematically illustrates the flowing direction of the cooling medium in the water tube as shown in FIG. 5B;

FIG. 6A is a schematic perspective view illustrating a portion of the water cooling device according to a sixth embodiment of the present invention;

FIG. 6B is a schematic perspective view illustrating a portion of the water tubes as shown in FIG. 1A and a portion of the communication structure and the water tank as shown in FIG. 6A;

FIG. 6C schematically illustrates the flowing direction of the cooling medium in the water tube as shown in FIG. 6B;

FIG. 7A is a schematic perspective view illustrating a portion of the water cooling device according to a seventh embodiment of the present invention;

FIG. 7B is a schematic perspective view illustrating a portion of the water tubes as shown in FIG. 1A and a portion of the communication structure and the water tank as shown in FIG. 7A;

FIG. 7C schematically illustrates the flowing direction of the cooling medium in the water tube as shown in FIG. 7B;

FIG. 8 is a schematic perspective view illustrating a portion of the water cooling device according to an eighth embodiment of the present invention; and

FIG. 9 is a schematic perspective view illustrating the application of a water cooling device according to a ninth embodiment of the present invention.

### DETAILED DESCRIPTION OF THE PREFERRED EMBODIMENT

The present invention provides a water cooling device. In the drawings, the three axial directions are defined as follows. The X-axial direction indicates the leftward/rightward direction of the water cooling device. The Y-axial direction indicates the forward/backward direction of the water cooling device. The Z-axial direction indicates the up/down direction of the water cooling device.

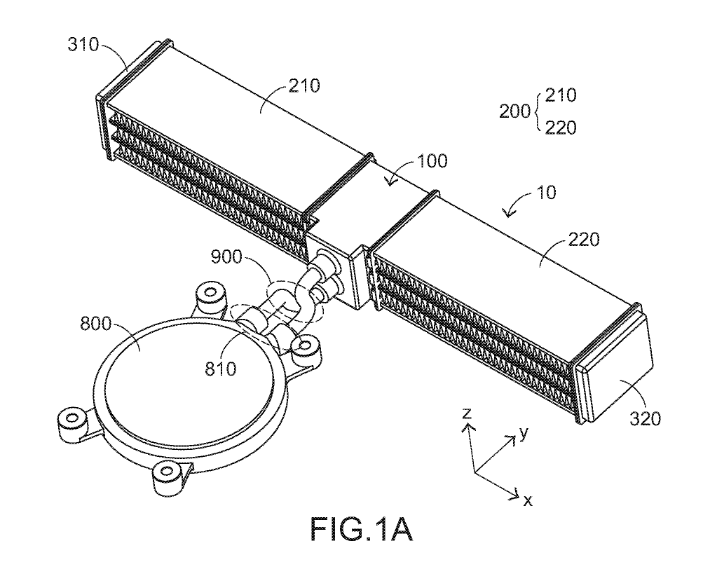

FIG. 1A is a schematic perspective view illustrating a water block and a water cooling device of a water cooling system according to a first embodiment of the present invention. FIG. 1B is a schematic perspective view illustrating a portion of the water cooling device as shown in FIG. 1A. FIG. 1C is a schematic perspective view illustrating a portion of the water tubes as shown in FIG. 1A and a portion of the communication structure and the water tank as shown in FIG. 1B. FIG. 1D schematically illustrates the flowing direction of the cooling medium in the water tube as shown in FIG. 1C.

Please refer to FIGS. 1A˜1D. The water cooling system comprises a water block 800, two conduits 900 and a water cooling device 10. The water cooling device 10 is in communication with the water block 800 through the two conduits 900. The water block 800 comprises an output/input end 810. The water cooling device 10 comprises a communication structure 100, a driving device 400, at least one water cooling structure 200, a first water tank 310 and a second water tank 320. In this embodiment, the water cooling structure 200 comprises a first water-cooling radiator 210 and a second water-cooling radiator 220.

The communication structure 100 is divided into a first chamber 111 and a second chamber 121 through a partition plate 100a. The first chamber 111 comprises a water inlet 110 and plural inlet ports A. The second chamber 121 comprises a water outlet 120 and plural outlet ports B. Both of the water inlet 110 and the water outlet 120 are formed in a lateral surface S30 (e.g., the XZ plane) of an outer periphery of the communication structure 100. That is, the water inlet 110 and the water outlet 120 are located at the same side (i.e., the lateral surface S30) of the communication structure 100. The water inlet 110 and the water outlet 120 are in communication with the output/input end 810 of the water block 800 through the two conduits 900. Consequently, the cooling medium such as water can be guided to flow through these components.

The way of dividing the communication structure 100 into the first chamber 111 and the second chamber 121 through the partition plate 100a is not restricted and may be varied according to the practical requirements.

The plural inlet ports A are aligned with the first chamber 111. The plural outlet ports B are aligned with the second chamber 121. Especially, the plural inlet ports A and the plural outlet ports B are formed in a first lateral surface S10 and a second lateral surface S20 of the communication structure 100. Moreover, the plural inlet ports A and the plural outlet ports B are in communication with plural water tubes 500 of the first water-cooling radiator 210 and the second water-cooling radiator 220. In this context, the water tubes 500 at the left side are also referred as first water tubes and the water tubes at the right side are also referred as second water tubes.

The first lateral surface S10 and the second lateral surface S20 of the communication structure 100 are arranged beside the first water-cooling radiator 210 and the second water-cooling radiator 220, respectively. The first water tank 310 and the second water tank 320 are located at two opposite sides of the left side and the right side of the XZ plane of the first water-cooling radiator 210 and the second water-cooling radiator 220. The plural inlet ports A are formed in the surfaces of the first chamber 111 that are in communication with the water tubes 500 of the two water-cooling radiators 210 and 220. The plural outlet ports B are formed in the surfaces of the second chamber 121 that are in communication with the water tubes 500 of the two water-cooling radiators 210 and 220. The driving device 400 is installed in at least one of the first chamber 111 and the second chamber 121.

The flowing direction of the cooling medium in the water cooling device will be described with reference to FIGS. 1C and 1D. The structures of FIGS. 1C and 1D are taken from the right viewpoint. After a first portion of the cooling medium is introduced into the water inlet 110, the cooling medium flows along a first flow-guiding direction W1. That is, the cooling medium flows through the first chamber 111, the plural inlet ports A, a portion of the second water tubes 500 (e.g., the upper-side water tubes), the second water tank 320, another portion of the second water tubes 500 (e.g., the lower-side water tubes), the plural outlet ports B, the second chamber 121 and the water outlet 120 sequentially.

The water outlet 120 is externally connected with the output/input end 810 of the water block 800. The water outlet 120 is in communication with the water inlet 110 through the output/input end 810. Consequently, a first flow-guiding path is defined.

The driving device 400 within second chamber 121 is used for pushing the cooling medium to the water outlet 120. Consequently, the cooling medium exits from the water cooling device 10. According to the practical requirements, the driving device 400 is a pump or a water pump for pushing or driving the flowing action of the cooling medium. As shown in FIG. 1B, the driving device 400 is installed in the second chamber 121. It is noted that the location of the driving device 400 is not restricted. For example, in another embodiment, the driving device 400 is installed in the first chamber 111.

As shown in FIG. 1D, the cooling medium flows within the water cooling structure 200 along the first flow-guiding direction W1. That is, the cooling medium is introduced from the upper-side inlet ports A of the communication structure 100 into the second water tank 320 along the first flow-guiding direction W1. Then, along the first flow-guiding direction W1, the cooling medium returns to the lower-side outlet ports B of the communication structure 100 through the water tubes 500 that are in communication with the lower portion of the second water tank 320. That is, the cooling water flows from the upper side of the water cooling device 10 to the lower side of the water cooling device 10 through the plural water tubes along the first flow-guiding direction W1.

On the other hand, a second portion of the cooling medium flows toward the left side of the water cooling device 10. After the second portion of the cooling medium is introduced into the water inlet 110, the cooling medium flows along another flow-guiding direction (not shown), which is symmetric to the first flow-guiding direction W1. That is, the cooling medium flows through the first chamber 111, the plural inlet ports A, a portion of the first water tubes 500, the first water tank 310, another portion of the second water tubes 500, the plural outlet ports B, the second chamber 121 and the water outlet 120 sequentially. Consequently, a second flow-guiding path is defined. Then, the second portion of the cooling medium along the second flow-guiding path and the first second portion of the cooling medium along the first flow-guiding path are mixed together in the output/input end 810 of the water block.

Especially, the location of the communication structure 100 may be varied according to the location of the water cooling device in the water cooling system. For example, the location of the communication structure of the water cooling device is determined according to the location of the output/input end of the water block.

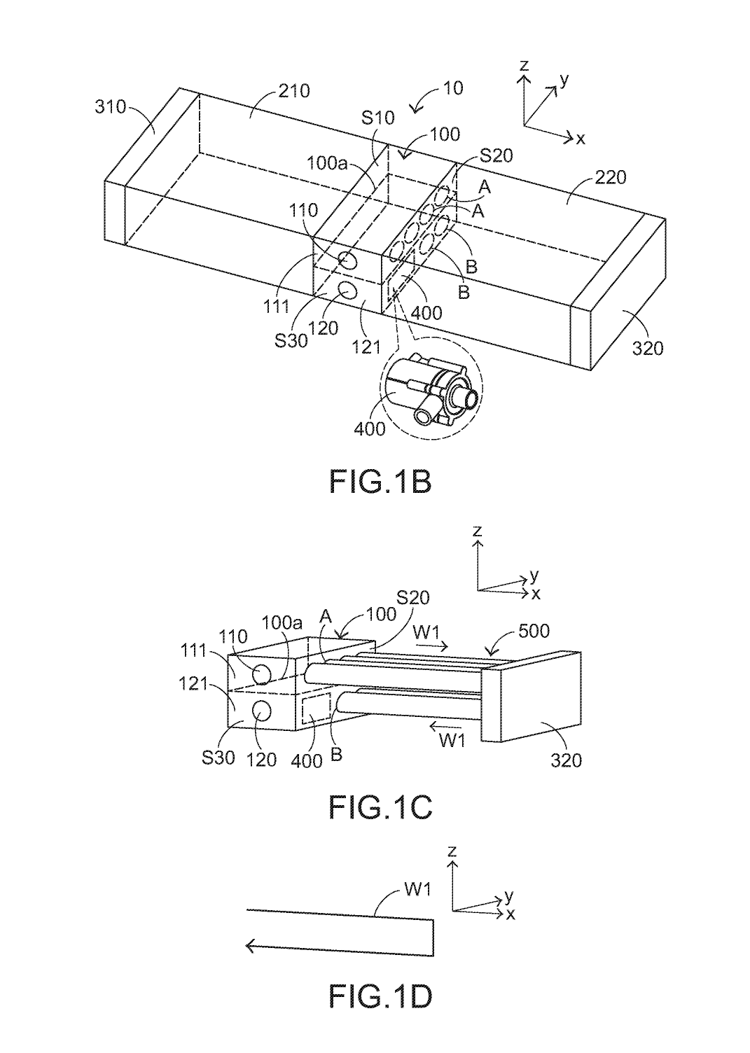

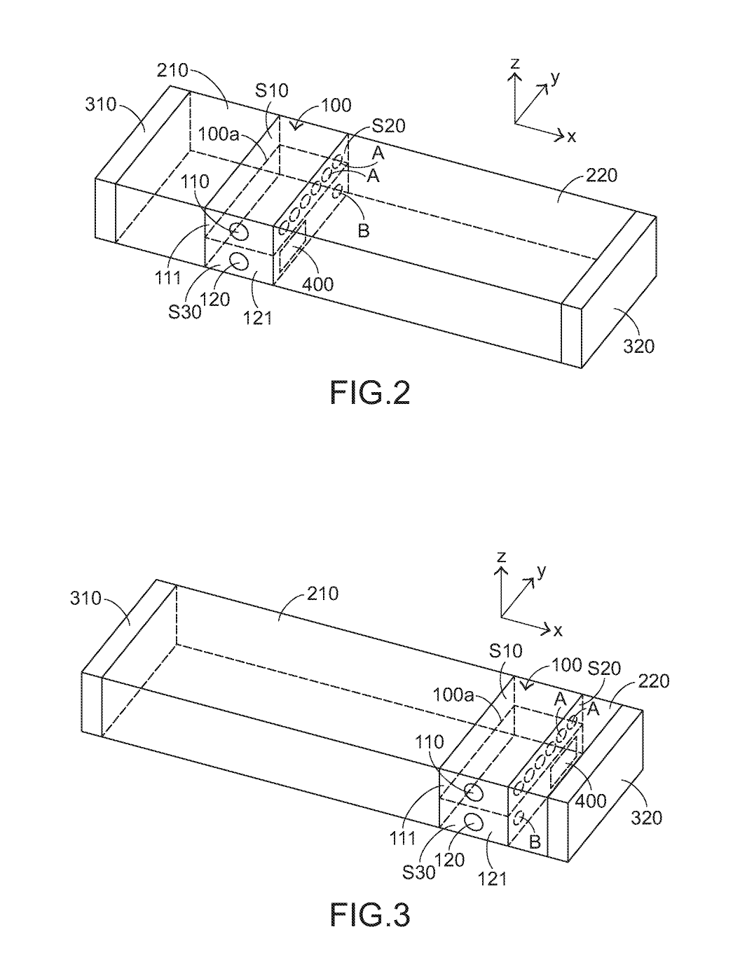

FIG. 2 is a schematic perspective view illustrating a portion of a water cooling device according to a second embodiment of the present invention, which is a variant example of FIG. 1B. FIG. 3 is a schematic perspective view illustrating a portion of the water cooling device according to a second embodiment of the present invention, which is another variant example of FIG. 1B. In comparison with the water cooling device of the first embodiment, the locations of the communication structures in the second embodiment and the third embodiment are distinguished. In the second embodiment of FIG. 2, the communication structure 100 is close to the first water tank 310 on the left side. In the third embodiment of FIG. 3, the communication structure 100 is close to the second water tank 320 on the right side.

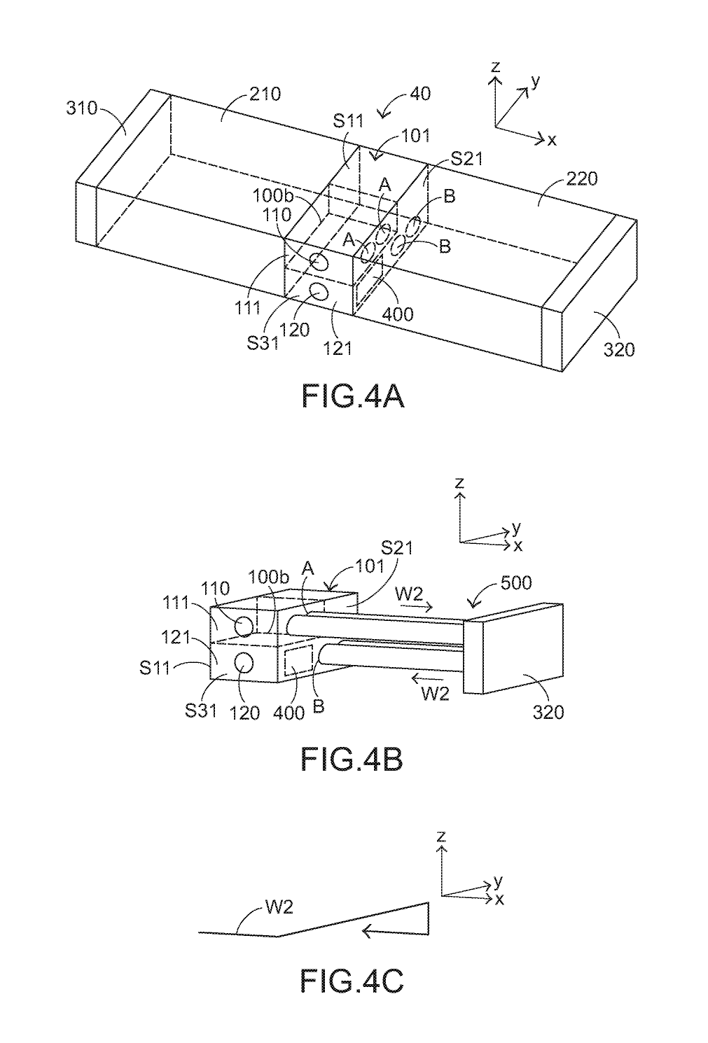

FIG. 4A is a schematic perspective view illustrating a portion of the water cooling device according to a fourth embodiment of the present invention. FIG. 4B is a schematic perspective view illustrating a portion of the water tubes as shown in FIG. 1A and a portion of the communication structure and the water tank as shown in FIG. 4A. FIG. 4C schematically illustrates the flowing direction of the cooling medium in the water tube as shown in FIG. 4B. In this embodiment, the partition plate 100b of the communication structure 101 is modified. Consequently, the first portion of the cooling medium flows along a second flow-guiding direction W2.

Like the third embodiment, a first lateral surface S11 and a second lateral surface S21 of the communication structure 101 are arranged beside the first water-cooling radiator 210 and the second water-cooling radiator 220, respectively. Both of the water inlet 110 and the water outlet 120 are formed in a lateral surface S31 (e.g., the XZ plane) of an outer periphery of the communication structure 101. That is, the water inlet 110 and the water outlet 120 are located at the same side (i.e., the lateral surface S31) of the communication structure 101.

In comparison with the above embodiments, the design and the location of the partition plate 100b of the communication structure 101 are modified. The locations of the plural inlet ports A in communication with the first water tubes and the second water tubes are changed. Consequently, the flow-guiding directions of the water-cooling radiators 210 and 220 of the water cooling structure 200 are adjusted. As shown in FIG. 4, the first portion of the cooling medium flows along the second flow-guiding direction W2.

In this embodiment, the inlet ports A are located at the right, upper and front side of the communication structure 101, and the outlet ports B are located at the rear and lower side of the communication structure 101. A first portion of the cooling medium flows from the plural inlet ports A to the second water tank 320 along the second flow-guiding direction W2. Then, the cooling medium returns to the outlet ports B through the rear and lower water tubes 500 in communication with the second water tank 320 along the second flow-guiding direction W2. In other words, the cooling medium flows from the front and upper side of the water cooling device 40 to the rear and lower side of the water cooling device 40 along the second flow-guiding direction W2.

In this embodiment, the driving device 400 is installed in at least one of the first chamber 111 and the second chamber 121 of the communication structure 101. Consequently, when the cooling medium is pushed by the driving device 400, the generated heat is not diffused to the heat dissipation region of the water cooling system. In addition, the space utilization of the overall water cooling system is enhanced.

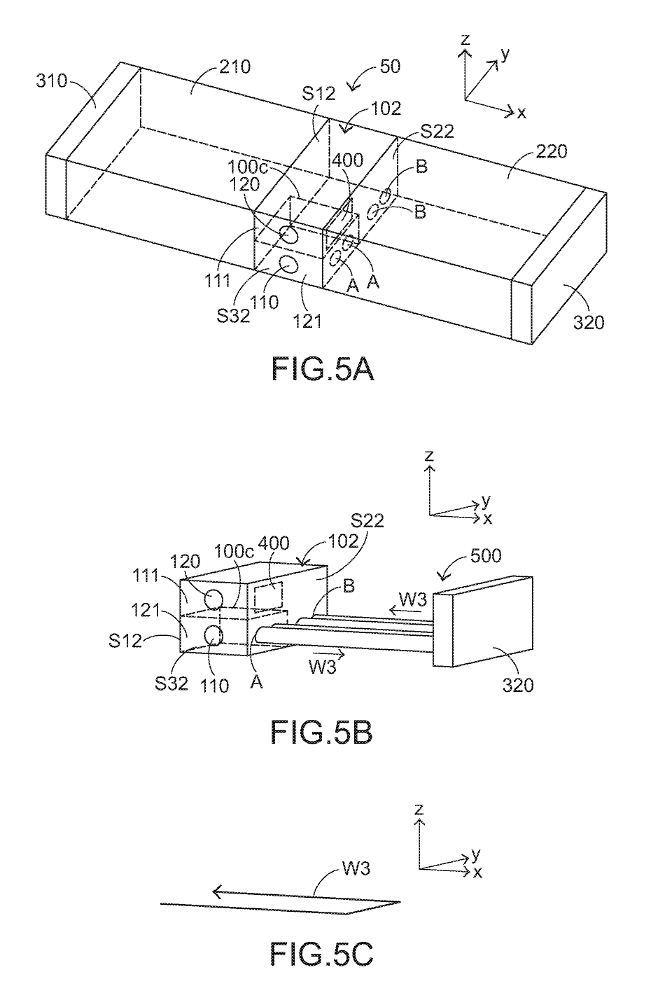

FIG. 5A is a schematic perspective view illustrating a portion of the water cooling device according to a fifth embodiment of the present invention. FIG. 5B is a schematic perspective view illustrating a portion of the water tubes as shown in FIG. 1A and a portion of the communication structure and the water tank as shown in FIG. 5A. FIG. 5C schematically illustrates the flowing direction of the cooling medium in the water tube as shown in FIG. 5B. A third flow-guiding direction W3 of the cooling medium in the fifth embodiment is similar to the second flow-guiding direction in the fourth embodiment. Like the third embodiment, a first lateral surface S12 and a second lateral surface S22 of the communication structure 102 of this embodiment are arranged beside the first water-cooling radiator 210 and the second water-cooling radiator 220, respectively. Both of the water inlet 110 and the water outlet 120 are formed in a lateral surface S32 (e.g., the XZ plane) of an outer periphery of the communication structure 102. That is, the water inlet 110 and the water outlet 120 are located at the same side (i.e., the lateral surface S32) of the communication structure 102.

In comparison with the above embodiments, the driving device 400 of the water cooling device 50 of this embodiment is installed in the first chamber 111. Moreover, as shown in FIG. 5A, the water outlet 120 is disposed over the water inlet 110. Since the partition plate 100c is specially designed, the third flow-guiding direction W3 is defined.

The third flow-guiding direction W3 of the cooling medium will be described with reference to FIGS. 5A˜5C. The structures of FIG. 5B are taken from the right viewpoint. The water inlet 110 is located at a lower side of the communication structure 102. After a first portion of the cooling medium is introduced into the water inlet 110, the cooling medium flows into a portion of water tubes 500 (e.g., the front and lower water tubes) from the inlet ports A at the lower side of the communication structure 102. Then, the cooling medium flows to the second water tank 320 at the right side S22 of the water cooling device 50 along the third flow-guiding direction W3. Then, the cooling medium flows to the rear side of the water cooling device 50 and flows into another portion of water tubes 500 (e.g., the rear and lower water tubes). Then, the cooling medium returns to the outlet ports B and the water outlet 120. Consequently, the third flow-guiding direction W3 of the cooling medium as shown in FIG. 5C is defined. The third flow-guiding direction W3 is similar to the second flow-guiding direction W2. That is, the cooling medium flows along the forward/backward direction of the water cooling device 50.

Moreover, the locations and structures of the first chamber and the second chamber of the communication structure in the water cooling device may be varied according to the practical requirements.

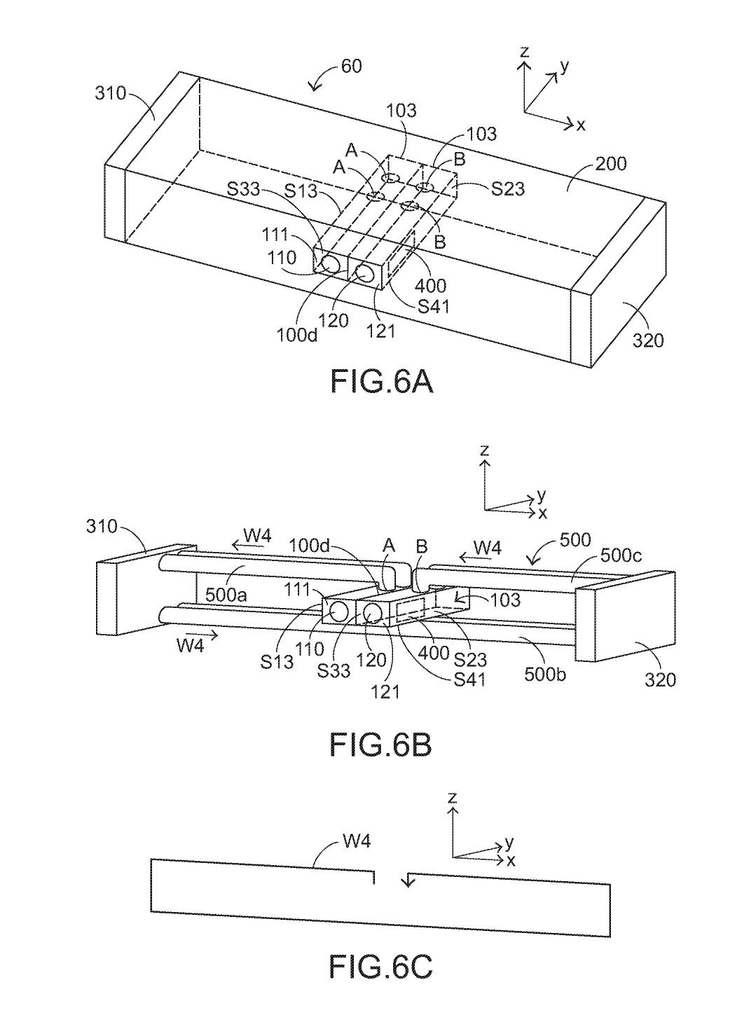

FIG. 6A is a schematic perspective view illustrating a portion of the water cooling device according to a sixth embodiment of the present invention. FIG. 6B is a schematic perspective view illustrating a portion of the water tubes as shown in FIG. 1A and a portion of the communication structure and the water tank as shown in FIG. 6A. FIG. 6C schematically illustrates the flowing direction of the cooling medium in the water tube as shown in FIG. 6B. In comparison with the above embodiments, the first chamber and the second chamber of the communication structure 103.

As shown in FIG. 6A, the communication structure 103 is installed in a water cooling structure 200. For example, the water cooling structure 200 is a single water-cooling radiator. A first water tank 310 is installed on a left surface of the water cooling structure 200. A second water tank 320 is installed on a right surface of the water cooling structure 200. A water inlet 110 and a water outlet 120 of the communication structure 103 are formed in a front surface of the water cooling device 60 (i.e., a front side S33) along the X-axial direction.

The communication structure 103 further comprises at least three lateral surfaces S13, S23 and S41. The three lateral surfaces S13, S23 and S41 are located beside a receiving surface of the water cooling structure 200. Moreover, the communication structure 103 is located near a middle region of the water cooling structure 200. Moreover, the communication structure 103 is divided into a first chamber 111 and a second chamber 121 through a partition plate 100d. The first chamber 111 and the second chamber 121 are located at the same level with each other. Since the contact area between the communication structure 103 and the water cooling structure 200 is increased, the heat dissipating efficiency and the heat transfer efficiency of the overall water cooling device 60 are enhanced.

The flow-guiding direction of the cooling medium in the water cooling device 60 of the sixth embodiment will be described with reference to FIGS. 6B and 6C. After the cooling medium flows into the first chamber 111 through the left water inlet 110 of the communication structure 103, the cooling medium flows along a fourth flow-guiding direction W4. That is, the cooling medium flows through the plural inlet ports A, first-portion water tubes 500a of the water tubes 500, the first water tank 310, second-portion water tubes 500b of the water tubes 500, the second water tank 320, third-portion water tubes 500c, the plural outlet ports B, the second chamber 121 and the water outlet 120 sequentially. The water outlet 120 is externally connected with the output/input end 810 of the water block 800. The water outlet 120 is in communication with the water inlet 110 through the output/input end 810. Consequently, a flow-guiding path is defined.

Similarly, the locations of the water inlet 110 and the water outlet 120 may be varied according to the flow-guiding direction of the cooling medium. In the sixth embodiment, the fourth flow-guiding direction W4 is a counterclockwise direction. For example, in another embodiment, the cooling medium is guided along a reverse direction of the fourth flow-guiding direction W4.

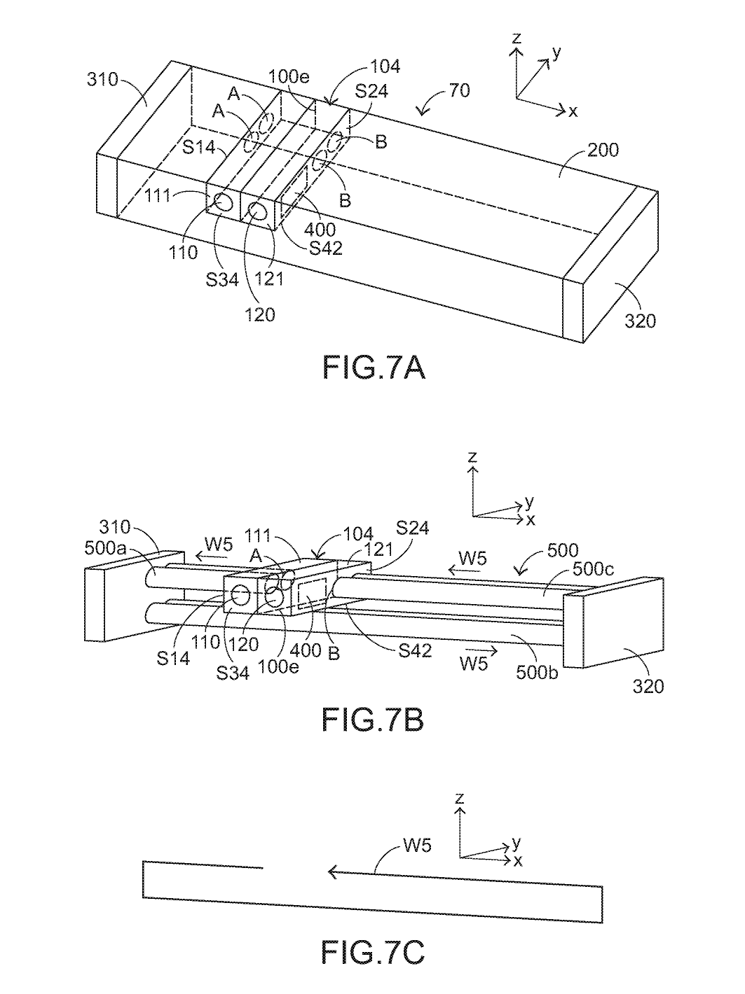

The location of the communication structure 103 may be varied according to the practical requirements. FIG. 7A is a schematic perspective view illustrating a portion of the water cooling device according to a seventh embodiment of the present invention. FIG. 7B is a schematic perspective view illustrating a portion of the water tubes as shown in FIG. 1A and a portion of the communication structure and the water tank as shown in FIG. 7A. FIG. 7C schematically illustrates the flowing direction of the cooling medium in the water tube as shown in FIG. 7B. In comparison with the sixth embodiment, a fifth flow-guiding direction W5 of the cooling medium is distinguished.

As shown in FIG. 7A, the communication structure 104 is located near an upper edge of the water cooling structure 200. Similarly, the communication structure 104 further comprises at least three lateral surfaces S14, S24 and S42. The three lateral surfaces S14, S24 and S42 are located beside a receiving surface of the water cooling structure 200. That is, the communication structure 104 is located near the upper edge of the water cooling structure 200, and the three lateral surfaces S14, S24 and S42 are located beside the water cooling structure 200. Moreover, the communication structure 104 is divided into a first chamber 111 and a second chamber 121 through a partition plate 100e.

In comparison with the communication structure 103 of the sixth embodiment, the communication structure 104 of this embodiment is specially designed. Consequently, the locations of the plural inlet ports A and the plural outlet ports B are changed. The plural inlet ports A are formed in the first chamber 111 and face the first water tank 310. The plural outlet ports B are formed in the second chamber 121 and face the second water tank 320.

The flow-guiding direction of the cooling medium in the water cooling device 70 of the seventh embodiment will be described with reference to FIGS. 7B and 7C.

As shown in FIG. 7B, the cooling medium flows into the first chamber 111 through the left water inlet 110 in the lateral surface S34 of the communication structure 104. The cooling medium flows along the fifth flow-guiding direction W5. That is, the cooling medium flows through the plural inlet ports A in the lateral surface S14 of the first chamber 111, first-portion water tubes 500a, the first water tank 310, second-portion water tubes 500b, the second water tank 320, third-portion water tubes 500c, the plural outlet ports B, the second chamber 121 and the water outlet 120 sequentially. The water outlet 120 is formed in the lateral surface S34 of the communication structure 104 and in communication with an external water block 800. That is, the cooling medium flows along the fifth flow-guiding direction W5 as shown in FIG. 7C.

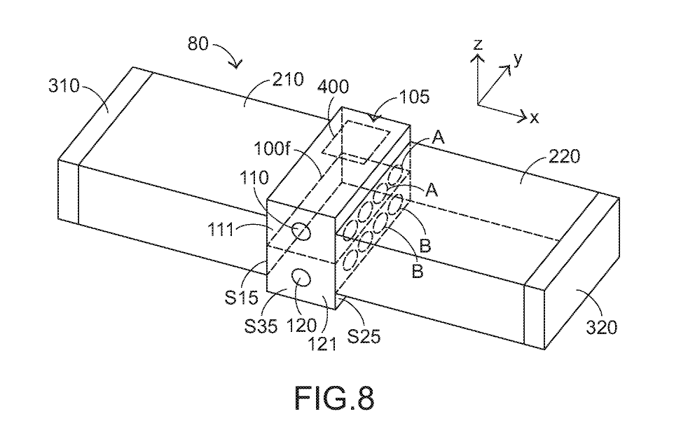

FIG. 8 is a schematic perspective view illustrating a portion of the water cooling device according to an eighth embodiment of the present invention. In this embodiment, the size of the communication structure is varied.

Please refer to FIG. 1B and FIG. 8. In comparison with the above embodiments, the size of the communication structure 105 is distinguished. Consequently, the size of the communication structure 105 matches the size of the driving device 400, which is installed in the communication structure 105. Under this circumstance, the driving device 400 is suitably installed in at least one of the first chamber 111 and the second chamber 112. Alternatively, the size of the communication structure 105 is adjusted according to the overall space utilization of the water cooling device 80.

Similarly, the communication structure 105 comprises at least three lateral surfaces S15, S25 and S35. A portion of the first lateral surface S15 is located beside and in communication with a surface of the first water-cooling radiator 210. A portion of the second lateral surface S25 is located beside and in communication with a surface of the second water-cooling radiator 220. The water inlet 110 and the water outlet 120 are formed in the third lateral surface S35. Moreover, the communication structure 105 is divided into a first chamber 111 and a second chamber 121 through a partition plate 100f. That is, portions of the at least two lateral surfaces S15 and S25 are respectively located beside and in communication with the first water-cooling radiator 210 and the second water-cooling radiator 220 according to the location and size of the communication structure 105.

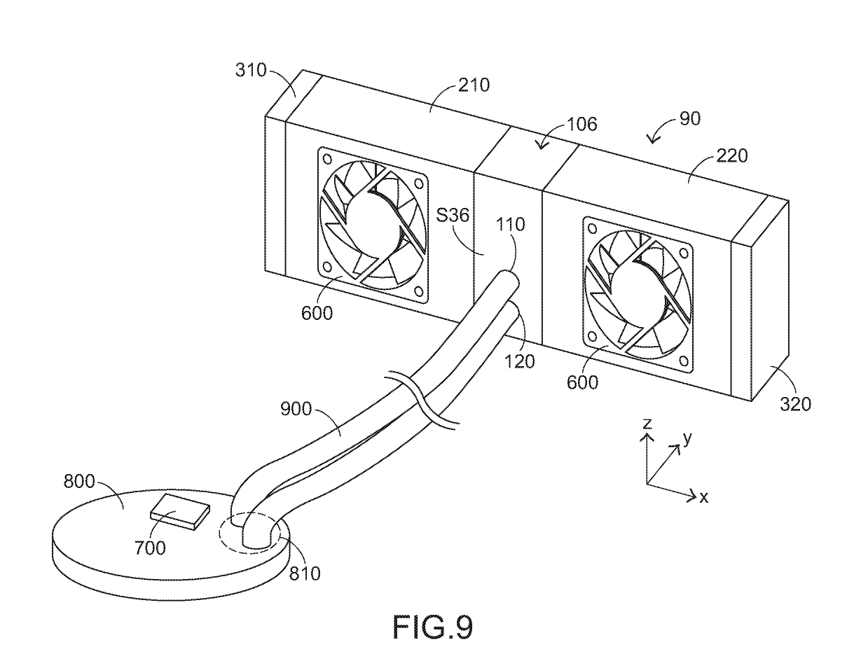

FIG. 9 is a schematic perspective view illustrating the application of a water cooling device according to a ninth embodiment of the present invention. The space layout of the water cooling device 90 in a water cooling system will be described as follows.

Please refer to the above drawings and FIG. 9. The water cooling system comprises a water cooling device 90, two conduits 900, two fans 600, a water block 800 and a heat generation unit 700. The water cooling device 90 comprises a communication structure 106 with a water inlet 110 and a water outlet 120, a first water-cooling radiator 210, a second water-cooling radiator 220, a first water tank 310 and a second water tank 320. The water block 800 comprises an output/input end 810.

The water inlet 110 and the water outlet 120 of the water cooling device 90 are in communication with the water block 800 through the two conduits 900. The two fans 600 are located beside the first water-cooling radiator 210 and the second water-cooling radiator 220, respectively. The heat generation unit 700 is disposed on a top surface of the water block 800. The water outlet 120 and the water inlet 110 of the communication structure 106 are formed in the same lateral surface S36 of the communication structure 106. The lateral surface S36 is located near the water block 800. Consequently, the two conduits 900 are in communication with the water cooling device 90 and the water block 800 along the same direction.

Since the water outlet 120 and the water inlet 110 are formed in the same lateral surface S36 of the communication structure 106, the space utilization of the water cooling system is enhanced. Moreover, since the water cooling device 90 is vertically located near the output/input end 810 of the water block 800, the layout space of the overall water cooling system is enhanced.

Alternatively, in another embodiment, the water cooling device 90 is horizontally located near the output/input end 810 of the water block 800. Moreover, the structure of the water cooling device 90 may be varied according to the requirements of the overall water cooling system. Like the above embodiments, the flow-guiding direction of the cooling medium in the water cooling device 90 may be changed according to the overall structure. Consequently, the flow-guiding direction of the cooling medium is changed. For example, the flow-guiding direction of the cooling medium may be varied according to the directions and locations of the water outlet 120 and the water inlet 110. It is noted that the above embodiments are presented herein for purpose of illustration and description only.

Moreover, the locations of the water inlet 110 and the water outlet 120 of the communication structure 106 may be exchanged. Under this circumstance, the cooling medium flows along the reverse directions of the flow-guiding directions W1˜W5. For example, in the embodiments from the first embodiment to the fifth embodiment, the cooling medium flows along a first flow-guiding direction after a first portion of the cooling medium is introduced into the water inlet. That is, the cooling medium flows through the first chamber, the plural inlet ports, a portion of the first water tubes, the first water tank, another portion of the first water tubes, the plural outlet port, the second chamber and the water outlet sequentially. Consequently, at least one exemplary first flow-guiding path is defined.

Moreover, a second portion of the cooling medium flows along a second flow-guiding direction. That is, the cooling medium flows through the first chamber, the plural inlet ports, a portion of the second water tubes, the second water tank, another portion of the second water tubes, the plural outlet ports, the second chamber and the water outlet sequentially. Consequently, at least one exemplary second flow-guiding path is defined. It is noted that the modifications of the water cooling device are not restricted by the flow-guiding paths of the above embodiments.

The structures, shapes and sizes of the components of the water cooling device are not restricted by the components of the above embodiments.

For example, in another embodiment, the plural water tubes of the water cooling structure are defined by plural fins, and the plural fins intersect with each other to define the water tubes in different densities. For describing the flowing direction of the water tubes, the water tubes shown in the drawings have the pipe configuration so as to illustrate the flow-guiding directions of the cooling medium. In the above embodiments, the water block and the communication structure are in communication with each other through the conduits. The conduits may be replaced with hard tubes or soft tubes.

Moreover, the fins of the water-cooling radiator may be adjusted according to the practical requirements. For example, the fins of the water-cooling radiator are adjusted according to the practical requirements of the product. Consequently, the heat dissipating performance of the water cooling device is adjusted.

Moreover, the structures, materials or shapes of the plural water tubes for guiding the cooling medium are not restricted. For example, the plural water tubes are flat tubes, circular tubes or any other appropriate tubes with various geometric profiles. The sizes of the water outlet and the water inlet of the communication structure may be varied according to the required heat dissipating performance. Consequently, the amount of the heat energy to be dissipated is adjusted.

Moreover, the sizes of the first chamber and the second chamber of the communication structure may be varied according to the design of the partition plate and the application structure (e.g. the driving device). Moreover, according to the at least one partition plate, the first chamber and the second chamber are horizontally located beside each other or vertically located beside each other.

From the above descriptions, the water cooling device of the present invention is equipped with two water tanks. Consequently, the variation capability of the flow-guiding direction of the cooling medium and the amount of the cooling medium are increased. Moreover, since the water inlet and the water outlet of the communication structure are located at the same side of the water cooling device, the space layout of the water cooling device is saved. Moreover, the driving device of the water cooling device is installed in at least one of the first chamber and the second chamber. Consequently, the generated heat of the driving device is not diffused to the heat dissipation region of the water cooling system. In addition, the space utilization of the overall water cooling system is enhanced. Consequently, the components of the water cooling device of the present invention may be varied according to the matched devices. Consequently, the overall space utilization is enhanced. Moreover, the purpose of increasing the heat dissipating performance is also achieved.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A water cooling device, comprising:
a water cooling structure with plural water tubes;
a communication structure with a first chamber and a second chamber, wherein the first chamber comprises a water inlet and plural inlet ports, and the second chamber comprises a water outlet and plural outlet ports; and
a driving device installed in at least one of the first chamber and the second chamber,
wherein the water inlet and the water outlet are formed in the same lateral surface of the communication structure, at least two additional lateral surfaces of the communication structure are located beside the water cooling structure, the plural water tubes are in communication with the plural inlet ports and the plural outlet ports, and a cooling medium is guided to flow through the plural water tubes.

2. The water cooling device according to claim 1, wherein the plural inlet ports are formed in a surface of the first chamber that is in communication with the plural water tubes, and the plural outlet ports are formed in a surface of the second chamber that is in communication with the plural water tubes, wherein the water cooling structure at least comprises a first water-cooling radiator and a second water-cooling radiator, wherein the first water-cooling radiator comprises first water tubes of the plural water tubes, the second water-cooling radiator comprises second water tubes of the plural water tubes, and the communication structure is arranged between the first water-cooling radiator and the second water-cooling radiator.

3. The water cooling device according to claim 2, wherein a first surface of the first water-cooling radiator is located beside a first one of the at least two additional lateral surfaces, a first water tank is in communication with the first water tubes and installed on a second surface of the first water-cooling radiator, a first surface of the second water-cooling radiator is located beside a second one of the at least two additional lateral surfaces, and a second water tank is in communication with the second water tubes and installed on a second surface of the second water-cooling radiator.

4. The water cooling device according to claim 3, wherein a portion of the cooling medium flows along a first flow-guiding direction and flows through the first chamber, the plural inlet ports, a first portion of the first water tubes, the first water tank, a second portion of the first water tubes, the plural outlet ports, the second chamber and the water outlet sequentially, so that a first flow-guiding path is defined.

5. The water cooling device according to claim 3, wherein a portion of the cooling medium flows along a second flow-guiding direction and flows through the first chamber, the plural inlet ports, a first portion of the second water tubes, the second water tank, a second portion of the second water tubes, the plural outlet ports, the second chamber and the water outlet sequentially, so that a second flow-guiding path is defined.

6. The water cooling device according to claim 2, wherein the water cooling structure comprises a water-cooling radiator with the plural water tubes, and the water-cooling radiator is located beside at least three lateral surfaces of the communication structure.

7. The water cooling device according to claim 6, wherein a receiving surface of the water-cooling radiator is located beside the at least three lateral surfaces of the communication structure, a first water tank is in communication with the plural water tubes and installed on a first surface of the water-cooling radiator, and a second water tank is in communication with the plural water tubes and installed on a second surface of the water-cooling radiator, wherein a portion of the cooling medium flows along a flow-guiding direction and flows through the first chamber, the plural inlet ports, a first portion of the plural water tubes, the first water tank, a second portion of the plural water tubes, the second water tank, a third portion of the plural water tubes, the plural outlet ports, the second chamber and the water outlet sequentially, so that a flow-guiding path is defined.

8. The water cooling device according to claim 1, wherein the water cooling structure is a combination of plural fins, and the plural fins intersect with each other to define the plural water tubes in different densities.

9. The water cooling device according to claim 1, wherein the communication structure is divided into the first chamber and the second chamber through at least one partition plate, wherein the first chamber and the second chamber are horizontally or vertically located beside each other through the at least one partition plate.

10. The water cooling device according to claim 1, wherein two ends of the driving device are in communication with the water inlet and the plural inlet ports, or the two ends of the driving device are in communication with the plural outlet ports and the water outlet.

11. A water cooling device, comprising:
a communication structure with a first chamber and a second chamber, wherein the first chamber comprises a water inlet and plural inlet ports, and the second chamber comprises a water outlet and plural outlet ports;
a driving device installed in at least one of the first chamber and the second chamber; and
a water cooling structure at least located beside a first lateral surface and a second lateral surface of the communication structure, and comprising plural water tubes, wherein the plural water tubes are in communication with the plural inlet ports and the plural outlet ports, and a cooling medium is guided to flow through the plural water tubes,
wherein the water outlet and the water inlet are in communication with an output/input end of a water block, wherein after the cooling medium flows from the first chamber to the plural water tubes and the cooling medium flows to the second chamber through the plural water tubes, the cooling medium exits to the water block and returns to the first chamber through the water block.

12. The water cooling device according to claim 11, wherein the water inlet and the water outlet are formed in a third lateral surface of the communication structure, and the water block is located near the third lateral surface of the communication structure.

13. The water cooling device according to claim 11, wherein the plural inlet ports are formed in a surface of the first chamber that is in communication with the plural water tubes, and the plural outlet ports are formed in a surface of the second chamber that is in communication with the plural water tubes, wherein the water cooling structure at least comprises a first water-cooling radiator and a second water-cooling radiator, wherein the first water-cooling radiator comprises first water tubes of the plural water tubes, the second water-cooling radiator comprises second water tubes of the plural water tubes, and the communication structure is arranged between the first water-cooling radiator and the second water-cooling radiator.

14. The water cooling device according to claim 13, wherein a first surface of the first water-cooling radiator is located beside one of the first lateral surface and the second lateral surface, and a first water tank is in communication with the first water tubes and installed on a second surface of the first water-cooling radiator.

15. The water cooling device according to claim 13, wherein a first surface of the first water-cooling radiator is located beside one of the first lateral surface and the second lateral surface, a first water tank is in communication with the first water tubes and installed on a second surface of the first water-cooling radiator, a first surface of the second water-cooling radiator is located beside the other of the first lateral surface and the second lateral surface, and a second water tank is in communication with the second water tubes and installed on a second surface of the second water-cooling radiator.

16. The water cooling device according to claim 15, wherein a portion of the cooling medium flows along a first flow-guiding direction and flows through the water inlet, the first chamber, the plural inlet ports, a first portion of the first water tubes, the first water tank, a second portion of the first water tubes, the plural outlet ports, the second chamber and the water outlet sequentially, so that a first flow-guiding path is defined.

17. The water cooling device according to claim 15, wherein a portion of the cooling medium flows along a second flow-guiding direction and flows through the water inlet, the first chamber, the plural inlet ports, a first portion of the second water tubes, the second water tank, a second portion of the second water tubes, the plural outlet ports, the second chamber and the water outlet sequentially, so that a second flow-guiding path is defined.

18. The water cooling device according to claim 12, wherein the water cooling structure comprises a water-cooling radiator with the plural water tubes, and a receiving surface of the water-cooling radiator is at least located beside the first lateral surface, the second lateral surface and the third lateral surface of the communication structure, wherein a first water tank is in communication with the plural water tubes and installed on a first surface of the water-cooling radiator, and a second water tank is in communication with the plural water tubes and installed on a second surface of the water-cooling radiator, wherein a portion of the cooling medium flows along a flow-guiding direction and flows through the water inlet, the first chamber, the plural inlet ports, a first portion of the plural water tubes, the first water tank, a second portion of the plural water tubes, the second water tank, a third portion of the plural water tubes, the plural outlet ports, the second chamber and the water outlet sequentially, so that a flow-guiding path is defined.

19. The water cooling device according to claim 11, wherein the communication structure is divided into the first chamber and the second chamber through at least one partition plate, wherein the first chamber and the second chamber are horizontally or vertically located beside each other through the at least one partition plate.

20. The water cooling device according to claim 11, wherein two ends of the driving device are in communication with the water inlet and the plural inlet ports, or the two ends of the driving device are in communication with the plural outlet ports and the water outlet.
